(19) United States
(12) Patent Application Publication
(10) Pub. No.: US 2025/0143150 A1
(43) Pub. Date: May 1, 2025

(54) DISPLAY DEVICE AND METHOD OF FABRICATING THE SAME

(71) Applicant: Samsung Display Co., LTD., Yongin-si (KR)

(72) Inventors: Yo Han KIM, Yongin-si (KR); Ji Eun KO, Yongin-si (KR); Won Min YUN, Yongin-si (KR); Hae Myeong LEE, Yongin-si (KR); Byoung Duk LEE, Yongin-si (KR); Seung Ju LEE, Yongin-si (KR); Su Min JUNG, Yongin-si (KR); Hye Young HAN, Yongin-si (KR)

(21) Appl. No.: 18/662,808

(22) Filed: May 13, 2024

(30) Foreign Application Priority Data
Oct. 30, 2023 (KR) 10-2023-0147247

(51) Int. Cl. H10K 59/80; H10K 59/38; H10K 102/00

(52) U.S. Cl. CPC H10K 59/879; H10K 59/38; H10K 59/877; H10K 2102/351

(57) ABSTRACT

A display device includes: a substrate comprising light-emitting areas and a non-light-emitting area; a light emitting element layer on the substrate; a thin-film encapsulation layer on the light emitting element layer; a wavelength conversion layer on the thin-film encapsulation layer; a binding member on the wavelength conversion layer and comprising an epoxy group; an opposing substrate facing the substrate; a color filter layer on a surface of the opposing substrate; and an auxiliary layer on the color filter layer and comprising an amine group, wherein the binding member and the auxiliary layer are in contact with each other, and the epoxy group of the binding member and the amine group of the auxiliary layer are chemically bonded to each other.

### CROSS-REFERENCE TO RELATED APPLICATION

The present application claims priority to and the benefit of Korean Patent Application No. 10-2023-0147247, filed on Oct. 30, 2023, in the Korean Intellectual Property Office, the entire disclosure of which is incorporated herein by reference.

### BACKGROUND

### 1. Field

Aspects of some embodiments of the present disclosure relate to a display device and a method of fabricating the same.

### 2. Description of the Related Art

As the information-oriented society evolves, consumer demand for display devices is ever increasing. For example, display devices may be utilized in a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices include, for example, organic light-emitting display devices including organic light-emitting elements, inorganic light-emitting display devices including inorganic light-emitting elements such as inorganic semiconductor, and micro light-emitting display devices including micro light-emitting elements.

An organic light-emitting element may include two opposing electrodes and an light emitting layer interposed therebetween. Electrons and holes supplied from the two electrodes are recombined in the light emitting layer to generate excitons, and the generated excitons relax from the excited state to the ground state so that light can be emitted.

An organic light-emitting display device including organic light-emitting elements may not utilize a separate light source such as a backlight unit, and thus it may consume relatively less power and can be made light and thin, as well as exhibit relatively high-quality characteristics such as a relatively wide viewing angle, relatively high luminance and contrast, and relatively fast response speed. Accordingly, organic light-emitting display devices are attracting attention as the next generation display device.

The above information disclosed in this Background section is only for enhancement of understanding of the background and therefore the information discussed in this Background section does not necessarily constitute prior art.

### SUMMARY

Aspects of some embodiments of the present disclosure include a display device that can relatively reduce fabrication costs with a relatively simpler structure, and a method of fabricating the same.

It should be noted that the characteristics of embodiments according to the present disclosure are not limited to the above-mentioned characteristics; and other characteristics of embodiments according to the present disclosure will be apparent to those skilled in the art from the following descriptions.

According to some embodiments of the present disclosure, a display device comprises a substrate comprising light-emitting areas and a non-light-emitting area, a light emitting element layer on the substrate, a thin-film encapsulation layer on the light emitting element layer, a wavelength conversion layer on the thin-film encapsulation layer, a binding member on the wavelength conversion layer and comprising an epoxy group, an opposing substrate facing the substrate, a color filter layer on a surface of the opposing substrate, and an auxiliary layer on the color filter layer and comprising an amine group, wherein the binding member and the auxiliary layer are in contact with each other, and the epoxy group of the binding member and the amine group of the auxiliary layer are chemically bonded to each other.

According to some embodiments, the binding member overlap with the non-light-emitting area and not overlap with the light-emitting areas.

According to some embodiments, the auxiliary layer overlaps with the light-emitting areas and the non-light-emitting area.

According to some embodiments, the binding member and the auxiliary layer are in contact with each other in the non-light-emitting area.

According to some embodiments, the binding member comprises an epoxy resin.

According to some embodiments, the auxiliary layer has a refractive index of 1.3 to 1.5.

According to some embodiments, a modulus of the auxiliary layer is 100 MPa to 1 GPa.

According to some embodiments, the auxiliary layer has a thickness of 1 μm to 5 μm.

According to some embodiments, the binding member has a thickness of 0.1 μm to 4.5 μm.

According to some embodiments, the display device further comprises an air layer in a space defined by the auxiliary layer, the binding member and the wavelength conversion layer, wherein the air layer overlaps with the light-emitting areas.

According to some embodiments, the binding member is arranged in a mesh pattern or a dot pattern when viewed from top.

According to some embodiments, a taper angle of the binding member ranges from 20° to 170°.

According to some embodiments, the light emitting element layer comprises a pixel electrode, a bank covering an edge of the pixel electrode, a light emitting layer on the pixel electrode, and a common electrode on the light emitting layer.

According to some embodiments, the light-emitting areas comprise a first light-emitting area emitting red light, a second light-emitting area emitting green light, and a third light-emitting area emitting blue light, and wherein the wavelength conversion layer comprises a first wavelength conversion pattern in line with the first light-emitting area, a second wavelength conversion pattern in line with the second light-emitting area, and a light-transmitting pattern in line with the third light-emitting area.

According to some embodiments of the present disclosure, a method of fabricating a display device, the method comprises preparing a substrate provided with an light emitting element layer, a thin-film encapsulation layer, and a wavelength conversion layer, forming a binding member comprising an epoxy group on the substrate, preparing an opposing substrate provided with a color filter layer, forming an auxiliary layer on the color filter layer, attaching an amine group to a surface of the auxiliary layer by performing surface treatment on the auxiliary layer, aligning and attaching the substrate with the opposing substrate to couple the binding member with the auxiliary layer, and performing a heat treatment process on the attached panel.

According to some embodiments, the binding member is formed by applying a bonding coating layer and patterning it via a photo process.

According to some embodiments, the performing surface treatment comprises using atmospheric-pressure nitrogen plasma or vacuum nitrogen plasma.

According to some embodiments, the heat treatment process is performed at a temperature of 90° C. to 110° C. for 30 to 60 minutes.

According to some embodiments, the amine group of the auxiliary layer and the epoxy group of the binding member are chemically bonded together in the heat treatment process.

According to some embodiments, the substrate and the opposing substrate are bonded together by vacuum bonding.

According to some embodiments of the present disclosure, an auxiliary layer is on a color filter layer and a binding member is on a wavelength conversion layer to couple them in a display device, so that a substrate and an opposing substrate can be more reliably coupled together.

According to some embodiments, an air layer is formed between the wavelength conversion layer and the auxiliary layer, so that light conversion efficiency and luminous efficiency can be improved.

It should be noted that the characteristics of embodiments according to the present disclosure are not limited to those described above and other characteristics of embodiments according to the present disclosure will be apparent to those skilled in the art from the following descriptions.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a plan view of a display device according to some embodiments of the present disclosure.

FIG. 2 is a view schematically showing lines included in the display device according to some embodiments of the present disclosure.

FIG. 3 is an equivalent circuit diagram of a sub-pixel according to some embodiments of the present disclosure.

FIG. 4 is a cross-sectional view schematically showing a display device according to some embodiments.

FIG. 5 is a cross-sectional view schematically showing a display area of the display device according to some embodiments.

FIG. 6 is a cross-sectional view schematically showing a display device according to some embodiments.

FIGS. 7 and 8 are views showing a bonding mechanism between a binding member and an auxiliary layer according to some embodiments.

FIG. 9 is a plan view showing an example of a layout of a binding member according to some embodiments of the present disclosure.

FIG. 10 is a plan view showing another example of a layout of a binding member according to some embodiments of the present disclosure.

FIGS. 11 to 13 are cross-sectional views showing examples of various shapes of binding members according to some embodiments.

FIGS. 14 to 16 are cross-sectional views showing processing steps of a method of fabricating a display device according to some embodiments of the present disclosure.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will more fully convey the scope of embodiments according to the present invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, aspects of some embodiments of the present disclosure will be described in more detail with reference to the accompanying drawings.

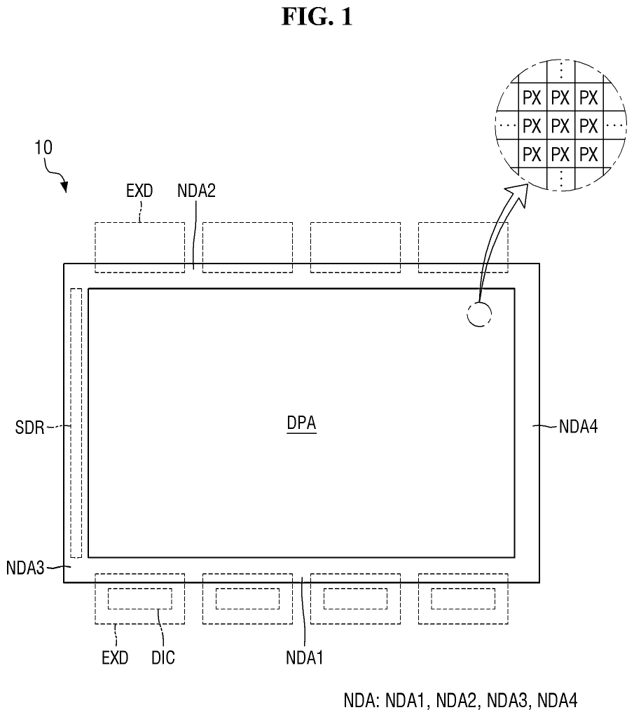

FIG. 1 is a plan view of a display device according to some embodiments of the present disclosure.

Referring to FIG. 1, a display device 10 according to some embodiments of the present disclosure may be applied to, a smart phone, a mobile phone, a tablet PC, a personal digital assistant (PDA), a portable multimedia player (PMP), a television set, a game machine, a wristwatch-type electronic device, a head-mounted display, a personal computer monitor, a laptop computer, a car navigation system, a car instrument cluster, a digital camera, a camcorder, an outdoor billboard, an electronic billboard, various medical apparatuses, various home appliances such as a refrigerator and a laundry machine, Internet of things (IoT) devices, etc. In the following description, a television is described as an example of the display device 10. TV may have a high resolution or ultra high resolution such as HD, UHD, 4K and 8K.

In addition, the display device 10 according to some embodiments may be variously classified by the way in which images are displayed. Examples of the classification of display device 10 may include an organic light-emitting display device (OLED), an inorganic light-emitting display device (inorganic EL), a quantum-dot light-emitting display device (QED), a micro LED display device (micro-LED), a nano LED display device (nano-LED), a plasma display device (PDP), a field emission display device (FED), a cathode ray display device (CRT), a liquid-crystal display device (LCD), an electrophoretic display device (EPD), etc. In the following description, an organic light-emitting display device and an inorganic light-emitting display device will be described as an example of the display device 10, and such light-emitting display devices will be simply referred to as display devices unless it is necessary to discern between them. It is, however, to be understood that the embodiments of the present disclosure are not limited to the organic light-emitting display device or an inorganic light-emitting display device, and one of the above-listed display devices or any other display device well known in the art may be employed without departing from the spirit and scope of embodiments according to the present disclosure.

According to some embodiments, the display device 10 may have a square shape, e.g., a rectangular shape when viewed from the top (e.g., in a plan view). When the display device 10 is a television, it is oriented such that the longer sides are positioned in the horizontal direction. It should be understood, however, that embodiments according to the present disclosure are not limited thereto. The longer side may be positioned in the vertical direction. Alternatively, the display device 1 may be installed rotatably so that the longer sides are positioned in the horizontal or vertical direction variably.

The display device 10 may include a display area DPA and a non-display area NDA. The display area DPA may be an active area where images are displayed. The display area DPA may have, but is not limited to, a rectangular shape similar to the general shape of the display device 10 when viewed from the top (e.g., in a plan view).

The display area DPA may include a plurality of pixels PX. The plurality of pixels PX may be arranged in a matrix. The shape of each of the pixels PX may be, but is not limited to, a rectangle or a square when viewed from the top (e.g., in a plan view). Each of the pixels PX may have a diamond shape having sides inclined with respect to a side of the display device 10. The plurality of pixels PX may include different color pixels PX. For example, the plurality of pixels PX may include, but is not limited to, a red first color pixel PX, a green second color pixel PX, and a blue third color pixel PX. The color pixels PX may be arranged alternately in a RGB stripe pattern or a PenTile™ matrix.

The non-display area NDA may be arranged around (e.g., in a periphery or outside a footprint of) the display area DPA. The non-display area NDA may surround the display area DPA entirely or partially. The display area DPA may have a rectangular shape, and the non-display area NDA may be arranged to be adjacent to the four sides of the display area DPA. The non-display area NDA may form the bezel of the display device 10.

In the non-display areas NDA, a driving circuit or a driving element for driving the display area DPA may be located. According to some embodiments of the present disclosure, a pad area is located on the display substrate of the display device 10 in a first non-display area NDA1 located adjacent to a first longer side (the lower side in FIG. 1) of the display device 10 and a second non-display area NDA2 adjacent to a second longer side (the upper side in FIG. 1) of the display device 1. An external device EXD may be mounted on a pad electrode of the pad area. Examples of the external devices EXD may include a connection film, a printed circuit board, a driver chip DIC, a connector, a line connection film, etc. A scan driver SDR formed directly on the display substrate of the display device 10 may be arranged in the third non-display area NDA3 located adjacent to a first shorter side of the display device 1 (the left side in FIG. 1). It should be understood, however, that embodiments according to the present disclosure are not limited thereto. The scan driver SDR may be located on a second shorter side (right side in FIG. 1) of the display device 10.

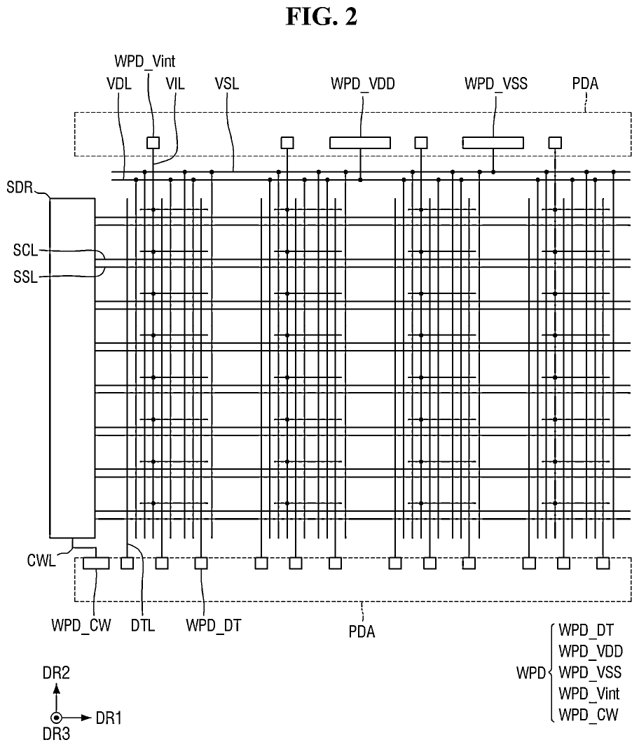

FIG. 2 is a view schematically showing lines included in the display device according to some embodiments of the present disclosure.

Referring to FIG. 2, the display device 10 may include a plurality of lines. The plurality of lines may include a scan line SCL, a sensing line SSL, a data line DTL, an initialization voltage line VIL, a first voltage line VDL, a second voltage line VSL, etc. In addition, according to some embodiments, other lines may be further located in the display device 10.

The scan line SCL and the sensing line SSL may be extended in the first direction DR1. The scan line SCL and the sensing line SSL may be connected to a scan driver SDR. The scan driver SDR may include a driving circuit. The scan driver SDR may be located on, but is not limited to, one side of the display area DPA in the first direction DR1. The scan driver SDR may be connected to a signal connection line CWL, and at least one end of the signal connection line CWL may form a pad WPD_CW on a pad area PDA in the non-display area to be connected to an external device.

As used herein, when an element is referred to as being “connected” or “coupled” to another element, it can be directly connected or coupled to the element or intervening elements may be present. In addition, such elements may be understood as a single integrated element and thus one portion thereof is connected to another portion. Moreover, when an element is referred to as being “connected” to another element, it may be in direct contact with the element and also electrically connected to the element.

The data line DTL and the initialization voltage line VIL may be extended in a second direction DR2 crossing the first direction DR1. The initialization voltage line VIL may further include branches as well as the portion extended in the second direction DR2. Each of the first voltage line VDL and the second voltage line VSL may also include portions extended in the second direction DR2 and portions connected thereto and extended in the first direction DR1. The first voltage line VDL and the second voltage line VSL may have, but is not limited to, a mesh structure. According to some embodiments, each of the pixels PX of the display device 10 may be connected to at least one data line DTL, the initialization voltage line VIL, the first voltage line VDL, and the second voltage line VSL.

The data line DTL, the initialization voltage line VIL, the first voltage line VDL and the second voltage line VSL may be electrically connected to one or more wire pads WPD. The wire pads WPD may be located in the pad area PDA. According to some embodiments of the present disclosure, a wire pad WPD_DT of the data line DTL (hereinafter referred to as a data pad) may be located in the pad area PDA on one side of the display area DPA in the second direction DR2, and a wire pad WPD_Vint of the initialization voltage line VIL (hereinafter referred to as an initialization voltage pad), a wire pad WPD_VDD of the first voltage line VDL (hereinafter referred to as a first power pad), and a wire pad WPD_VSS of the second voltage line VSL (hereinafter referred to as a power pad) may be located in the pad area PDA located on the other side of the display area DPA in the second direction DR2. As another example, the data pad WPD_DT, the initialization voltage pad WPD_Vint and the first supply voltage pad WPD_VDD and the second supply voltage pad WPD_VSS may all be located in the same area, e.g., in the non-display area NDA on the upper side of the display area DPA. External devices EXD may be mounted on the wire pads WPD. The external devices EXD may be mounted on the wire pads WPD by an anisotropic conductive film, ultrasonic bonding, etc.

Each of the pixels PX or sub-pixels PXn of the display device 10 includes a pixel driving circuit, where n is an integer of 1 to 3. The above-described lines may pass through each of the pixels PX or the periphery thereof to apply a driving signal to the pixel driving circuit. The pixel driving circuit may include transistors and a capacitor. The numbers of transistors and capacitors of each pixel driving circuit may be changed in a variety of ways. According to some embodiments of the present disclosure, each of the sub-pixels SPXn of the display device 10 may have a 3T1C structure, i.e., a pixel driving circuit includes three transistors and one capacitor. In the following description, the pixel driving circuit having the 3T1C structure will be described as an example. It is, however, to be understood that embodiments according to the present disclosure are not limited thereto. A variety of modified pixel structure may be employed such as a 2T1C structure, a 7T1C structure and a 6T1C structure.

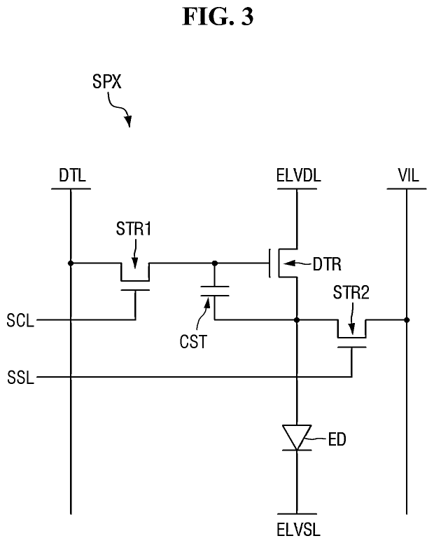

FIG. 3 is an equivalent circuit diagram of a sub-pixel according to some embodiments of the present disclosure.

Referring to FIG. 3, each of the sub-pixels SPX of the display device 10 according to some embodiments includes three transistors DTR, STR1 and STR2 and one storage capacitor Cst in addition to a light-emitting element ED.

The light-emitting element ED emits light in proportional to the current supplied through the driving transistor DTR. The light-emitting element ED may be implemented as an inorganic light-emitting diode, an organic light-emitting diode, a micro light-emitting diode, a nano light-emitting diode, etc.

The first electrode (i.e., the anode electrode) of the light-emitting diode ED may be connected to the source electrode of the driving transistor DTR, and the second electrode (i.e., the cathode electrode) thereof may be connected to a second supply voltage line ELVSL, from which a low-level voltage (second supply voltage) is applied, lower than a high-level voltage (first supply voltage) of a first supply voltage line ELVDL.

The driving transistor DTR adjusts a current flowing from the first supply voltage line ELVDL from which the first supply voltage is applied to the light-emitting element ED according to the voltage difference between the gate electrode and the source electrode. The gate electrode of the driving transistor DTR may be connected to a first electrode of the first transistor STR1, the source electrode may be connected to a first electrode of the light-emitting element ED, and the drain electrode may be connected to the first supply voltage line ELVDL from which the first supply voltage is applied.

The first transistor STR1 is turned on by a scan signal of a scan line SCL to connect a data line DTL with the gate electrode of the driving transistor DTR. A gate electrode of the first transistor STR1 may be connected to the scan line SCL, the first electrode thereof may be connected to the gate electrode of the driving transistor DTR, and a second electrode thereof may be connected to the data line DTL.

The second transistor STR2 may be turned on by a sensing signal of a sensing signal line SSL to connect the initialization voltage line VIL to the source electrode of the driving transistor DTR. A gate electrode of the second transistor STR2 may be connected to the sensing signal line SSL, a first electrode thereof may be connected to the initialization voltage line VIL, and a second electrode thereof may be connected to the source electrode of the driving transistor DTR.

According to some embodiments of the present disclosure, the first electrode of each of the first and second transistors STR1 and STR2 may be a source electrode while the second electrode thereof may be a drain electrode. It is, however, to be understood that the present disclosure is not limited thereto. The first electrode of each of the first and second switching transistors STR1 and STR2 may be a drain electrode while the second electrode thereof may be a source electrode.

The capacitor CST may be formed between the gate electrode and the source electrode of the driving transistor DTR. The storage capacitor CST stores a voltage difference between the gate voltage and the source voltage of the driving transistor DTR.

The driving transistor DTR and the first and second transistors STR1 and STR2 may be formed as thin-film transistors. In addition, although FIG. 3 shows that each of the driving transistor DTR and the first and second switching transistors STR1 and STR2 is implemented as an n-type MOSFET (metal oxide semiconductor field effect transistor), it is to be noted that the present disclosure is not limited thereto. That is to say, the driving transistor DTR and the first and second switching transistors STR1 and STR2 may be implemented as p-type MOSFETs, or some of them may be implemented as n-type MOSFETs while the others may be implemented as p-type MOSFETs.

Although various components are illustrated in the sub-pixel SPX of FIG. 3, embodiments according to the present disclosure are not limited thereto, and according to various embodiments, there may be fewer components or additional components without departing from the spirit and scope of embodiments according to the present disclosure.

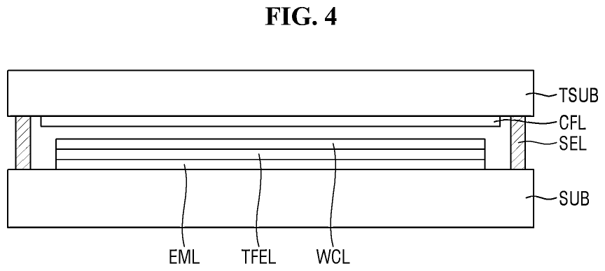

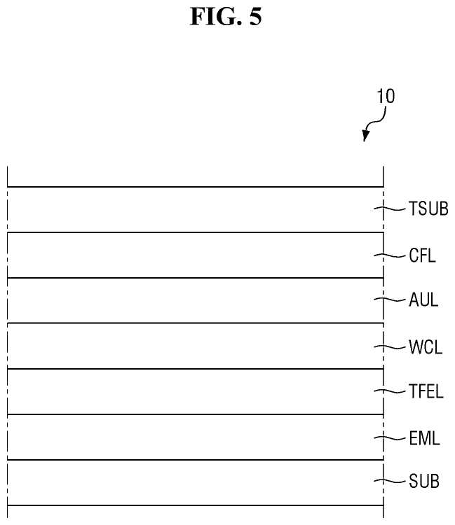

FIG. 4 is a cross-sectional view schematically showing a display device according to some embodiments. FIG. 5 is a cross-sectional view schematically showing a display area of the display device according to some embodiments.

Referring to FIGS. 4 and 5, the display device 10 according to some embodiments of the present disclosure may include a substrate SUB, a light emitting element layer EML, a thin-film transistor layer TFTL, a wavelength conversion layer WCL, a color filter layer CFL, a opposing substrate TSUB and a sealing member SEL.

The substrate SUB may be an insulating substrate. The substrate SUB may include a transparent material. For example, the substrate SUB may include a transparent insulating material such as glass and quartz. The substrate SUB may be a rigid substrate. In addition, the substrate SUB is not limited to those described above. The substrate SUB may include a plastic such as polyimide, or may be flexible so that it can be curved, bent, folded or rolled.

The light emitting element layer EML may be located on the substrate SUB. The light emitting element layer EML may include a plurality of switching elements and a plurality of light-emitting elements ED located in each sub-pixel. The switching elements may drive light-emitting elements ED so that the light emitting elements ED emit light.

The thin-film encapsulation layer TFEL may be located on the light emitting element layer EML. The thin-film encapsulation layer TFEL may include an organic film located between a plurality of inorganic films and can protect the light emitting element layer EML from outside moisture and oxygen.

The wavelength conversion layer WCL may be located on the thin-film encapsulation layer TFEL. The wavelength conversion layer WCL may convert the wavelength of light emitted from the light emitting element layer EML to emit red light, green light and blue light.

The color filter layer CFL may be located on a surface of the opposing substrate TSUB. The color filter layer CFL can filter light incident from the outside to reduce reflection of external light and improve the color characteristics of light emitted through the wavelength conversion layer WCL.

The opposing substrate TSUB may be located on the color filter layer CFL. The opposing substrate TSUB may encapsulate the light emitting element layer EML together with the substrate SUB. The opposing substrate TSUB may include a transparent material. For example, the opposing substrate TSUB may include a transparent insulating material such as glass and quartz.

A seal member SEL may be located between the substrate SUB and the opposing substrate TSUB. The seal member SEL may seal the light emitting element layer EML by coupling the substrate SUB with the opposing substrate TSUB. The seal member SEL may contain an organic material or an inorganic material. The organic material may be, for example, a sealant, and the inorganic material may be, for example, a glass frit. It should be understood, however, that embodiments according to the present disclosure are not limited thereto. The seal member SEL may include a moisture-absorbing material such as a metal oxide. For example, the content of the moisture-absorbing material in the total composition of the seal member may be equal to or less than approximately 20 wt %.

Hereinafter, the elements of a display device according to some embodiments of the present disclosure will be described in more detail with reference to other drawings.

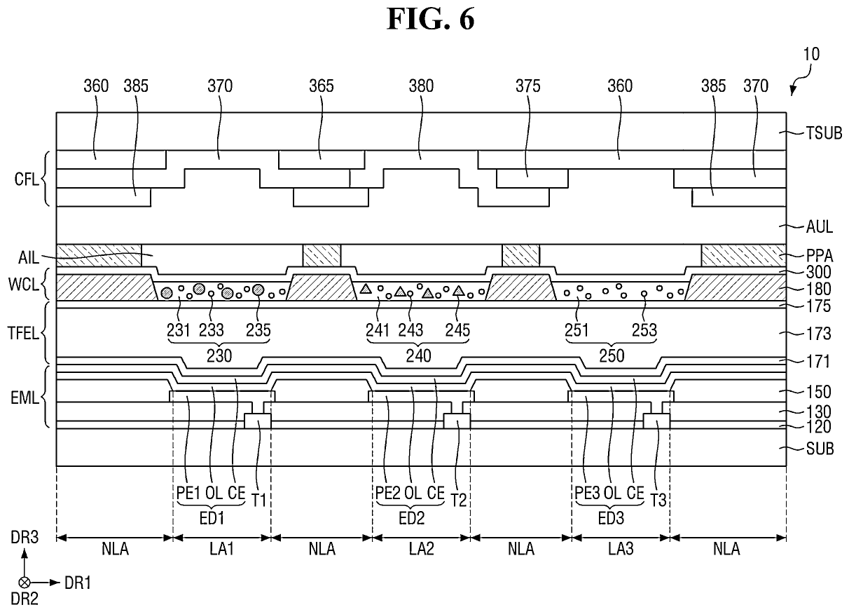

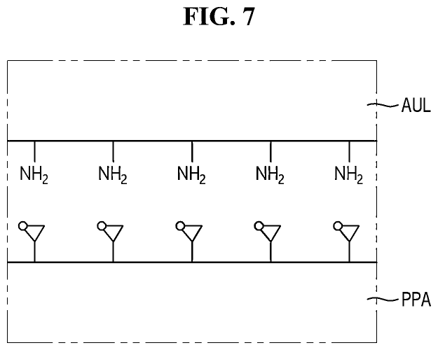

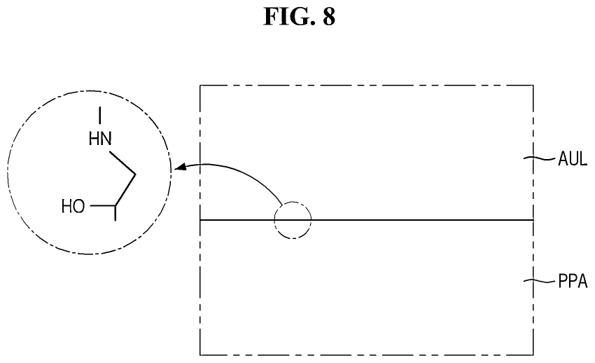

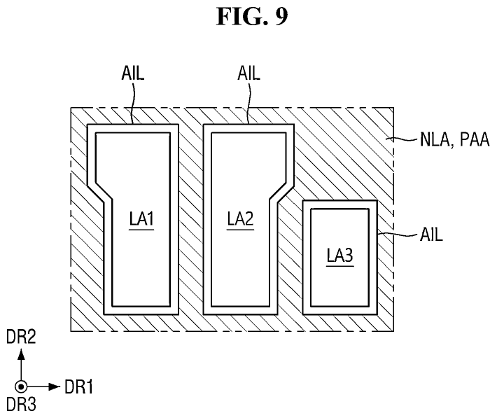

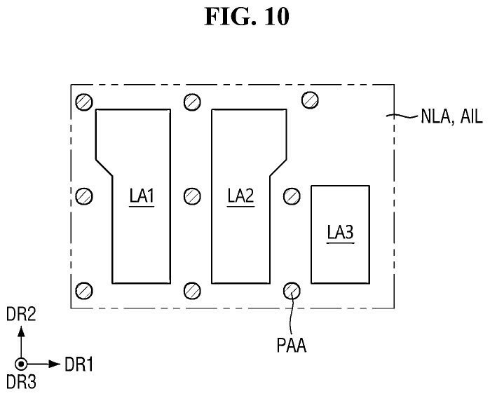

FIG. 6 is a cross-sectional view schematically showing a display device according to some embodiments. FIGS. 7 and 8 are views showing a bonding mechanism between a binding member and an auxiliary layer according to some embodiments. FIG. 9 is a plan view showing an example of a layout of a binding member according to some embodiments of the present disclosure. FIG. 10 is a plan view showing another example of a layout of a binding member according to some embodiments of the present disclosure.

Referring to FIGS. 6 and 10, the display device 10 according to some embodiments of the present disclosure may include a substrate SUB, a light emitting element layer EML, a thin-film transistor layer TFTL, a wavelength conversion layer WCL, a bonding member PPA, an auxiliary layer AUL, an air layer AIL, a color filter layer CFL, and an opposing substrate TSUB.

A plurality of light-emitting areas LA1, LA2 and LA3 and a non-light-emitting area NLA may be defined on the substrate SUB. In the light-emitting areas LA1, LA2 and LA3, lights generated in the light-emitting elements ED1, ED2 and ED3 may exit. In the non-light-emitting area NLA, no light may exit. According to some embodiments, a first light-emitting area LA1, a second light-emitting area LA2 and a third light-emitting area LA3 may be arranged repeatedly in this order in the first direction DR1 in the display area DPA.

The first light-emitting area LA1, the second light-emitting area LA2 and the third light-emitting area LA3 may have the same width measured in the first direction DR1. It should be understood, however, that the present disclosure is not limited thereto. The first light-emitting area LA1, the second light-emitting area LA2 and the third light-emitting area LA3 may have different widths measured in the first direction DR1. For example, the width of the third light-emitting area LA3 may be smaller than the width of the second light-emitting area LA2, and the width of the second light-emitting area LA2 may be smaller than the width of the first light-emitting area LA1.

The light-emitting areas LA1, LA2 and LA3 may emit lights of different colors. According to some embodiments of the present disclosure, the first light-emitting area LA1 may emit light of a first color, the second light-emitting area LA2 may emit light of a second color, and the third light-emitting area LA3 may emit light of a third color. According to some embodiments of the present disclosure, the light of the first color may be red light with a peak wavelength in the range of approximately 610 nm to 650 nm, the light of the second color may be green light with a peak wavelength in the range of 510 nanometers (nm) to 550 nm (or approximately 510 nm to 550 nm), and the light of the third color may be blue light with a peak wavelength in the range of 440 nm to 480 nm (or approximately 440 nm to 480 nm). It should be understood, however, that embodiments according to the present disclosure are not limited thereto. The light of the first color may be green light and the light of the second color may be red light.

On the substrate SUB, switching elements T1, T2 and T3 may be located. According to some embodiments of the present disclosure, the first switching element T1 may be located in the first light-emitting area LA1 of the substrate SUB, the second switching element T2 may be located in the second light-emitting area LA2, and the third switching element T3 may be located in the third light-emitting area LA3. It is, however, to be understood that the present disclosure is not limited thereto. In other embodiments, at least one of the first switching device T1, the second switching device T2, or the third switching device T3 may be located in the non-light-emitting area NLA.

According to some embodiments of the present disclosure, each of the first switching element T1, the second switching element T2 and the third switching element T3 may be a thin-film transistor including amorphous silicon, polysilicon, or an oxide semiconductor. According to some embodiments, a plurality of signal lines (e.g., gate lines, data lines, power lines, etc.) for transmitting signals to the switching elements may be further located on the substrate SUB. In addition, the switching elements T1, T2 and T3 may include a first insulating layer 120. For example, the first insulating layer 120 may be a gate insulator or an interlayer dielectric film of a thin-film transistor. The gate insulator or the interlayer dielectric film may be made up of a single layer including one of silicon oxide (SiOx), silicon nitride oxide (SiOxNy), and silicon nitride (SiNx), or multiple layers thereof.

A second insulating layer 130 may be located over the first switching element T1, the second switching element T2 and the third switching element T3. According to some embodiments of the present disclosure, the second insulating layer 130 may be a planarization film. According to some embodiments of the present disclosure, the second insulating layer 130 may be formed as an organic film. For example, the second insulating layer 130 may include an acrylic resin, an epoxy resin, an imide resin, an ester resin, etc. According to some embodiments of the present disclosure, the second insulating layer 130 may include a positive photoresist or a negative photoresist.

The first pixel electrode PE1, the second pixel electrode PE2 and the third pixel electrode PE3 may be located on the second insulating layer 130. The first pixel electrode PE1 may be located in the first light-emitting area LA1 and may be extended to the non-light-emitting area NLA at least partially. The second pixel electrode PE2 may be located in the second light-emitting area LA2 and may be extended to the non-light-emitting area NLA at least partially. The third pixel electrode PE3 may be located in the third light-emitting area LA3 and may be extended to the non-light-emitting area NLA at least partially. The first pixel electrode PE1 may be connected to the first switching element T1 through the second insulating layer 130, the second pixel electrode PE2 may be connected to the second switching element T2 through the second insulating layer 130, and the third pixel electrode PE3 may be connected to the third switching element T3 through the second insulating layer 130.

According to some embodiments of the present disclosure, the widths or areas of the first pixel electrode PE1, the second pixel electrode PE2 and the third pixel electrode PE3 may be different from one another. It should be understood, however, that the present disclosure is not limited thereto. The widths or areas of the first pixel electrode PE1, the second pixel electrode PE2 and the third pixel electrode PE3 may be different from one another. For example, the width of the third pixel electrode PE3 may be smaller than the width of the second pixel electrode PE2, and the width of the second pixel electrode PE2 may be smaller than the width of the first pixel electrode PE1 and may be greater than the width of the third electrode PE3. Alternatively, the width of the third pixel electrode PE3 may be smaller than the width of the second pixel electrode PE2, and the width of the second pixel electrode PE3 may be smaller than the width of the first pixel electrode PE1 and may be greater than the width of the third electrode PE3.

The first pixel electrode PE1, the second pixel electrode PE2 and the third pixel electrode PE3 may be reflective electrodes. The first pixel electrode AE1, the second pixel electrode AE2 and the third pixel electrode AE3 may have a stack structure of a material layer having a high work function such as indium tin oxide (ITO), indium zinc oxide (IZO), zinc oxide (ZnO), indium tin zinc oxide (ITZO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca) or a mixture thereof. A material layer having a higher work function may be located on a higher layer than a reflective material layer so that it may be closer to a light emitting layer OL. The first pixel electrode PE1, the second pixel electrode PE2 and the third pixel electrode PE3 may have, but is not limited to, a multilayer structure of ITO/Mg, ITO/MgF, ITO/Ag, and ITO/Ag/ITO.

A pixel-defining layer 150 may be located on the first pixel electrode PE1, the second pixel electrode PE2, and the third pixel electrode PE3. The pixel-defining layer 150 may include an opening exposing the first pixel electrode PE1, an opening exposing the second pixel electrode PE2 and an opening exposing the third pixel electrode PE3, and may define the first light-emitting area LA1, the second light-emitting area LA2, the third light-emitting LA3 and the non-light-emitting area NLA. Specifically, a portion of the first pixel electrode PE1 that is not covered by the pixel-defining layer 150 but is exposed may be the first light-emitting area LA1. A portion of the second pixel electrode PE2 that is not covered by the pixel-defining layer 150 but is exposed may be the second light-emitting area LA2. A portion of the third pixel electrode PE3 that is not covered by the pixel-defining layer 150 but is exposed may be the third light-emitting area LA3. The other portions where the pixel-defining layer 150 is located may be the non-light-emitting area NLA.

The pixel-defining layer 150 may include an organic insulating material such as a polyacrylate resin, an epoxy resin, a phenolic resin, a polyamide resin, a polyimide resin, an unsaturated polyester resin, a polyphenylene resin, a poly phenylene sulfide resin, and benzocyclobutene (BCB).

According to some embodiments of the present disclosure, the pixel-defining layer 150 may overlap with a bank 180 of the wavelength conversion layer WCL to be described later. The light emitting layer OL may be located on the first pixel electrode PE1, the second pixel electrode PE2, and the third pixel electrode PE3. According to some embodiments where the display device 10 is an organic light-emitting display device, the light emitting layer OL may include an organic layer containing an organic material. The organic layer includes an organic light emitting layer and may further include at least one of: a hole injection layer, a hole transport layer, an electronic transport layer, or an electron injection layer as an auxiliary layer in some implementations in order to facilitate light emission.

According to some embodiments of the present disclosure, the light emitting layer OL may have a tandem structure including a plurality of organic light emitting layers overlapping one another in the thickness direction and a charge generation layer located therebetween. The organic light emitting layer overlapping one another may emit either light of the same wavelength or lights of different wavelengths. For example, the overlapping organic light emitting layers may include an organic light emitting layer that emits light in a green wavelength and an organic light emitting layer that emits light in a blue wavelength. According to some embodiments, the overlapping organic light emitting layers may include an organic light emitting layer that emits light in a red wavelength, an organic light emitting layer that emits light in a green wavelength, and an organic light emitting layer that emits light in a blue wavelength.

According to some embodiments of the present disclosure, the light emitting layer OL may have the shape of a continuous film arranged across the light-emitting areas LA1, LA2 and LA3 and the non-light-emitting area NLA. In this instance, the wavelengths of lights emitted from the light emitting layer OL may be the same. For example, the light emitting layer OL may emit blue light, light of white wavelength or ultraviolet light from the plurality of light-emitting areas LA1, LA2 and LA3.

The common electrode CE may be located on the light emitting layer OL. The common electrode CE may be a cathode electrode of each of the light-emitting elements ED1, ED2 and ED3. According to some embodiments of the present disclosure, the common electrode CE may be semi-transmissive or transmissive. If the common electrode CE is semi-transmissive, the common electrode CE may include Ag, Mg, Cu, Al, Pt, Pd, Au, Ni, Nd, Ir, Cr, Li, Ca, LiF/Ca, LiF/Al, Mo, Ti or a compound or a mixture thereof, e.g., a mixture of Ag and Mg. Further, if the thickness of the common electrode CE ranges from several tens to several hundred angstroms, the common electrode CE may be semi-transmissive.

When the common electrode CE is transmissive, the common electrode CE may include a transparent conductive oxide (TCO). For example, the common electrode CE may be formed of tungsten oxide (WxOy), titanium oxide (TiO₂), indium tin oxide (ITO), indium zinc oxide (IZO), zinc oxide (ZnO), indium tin zinc oxide MgO (magnesium oxide), etc.

The first pixel electrode PE1, the light emitting layer OL and the common electrode CE may form a first light-emitting element ED1, the second pixel electrode PE2, the light emitting layer OL and the common electrode CE may form a second light-emitting element ED2, and the third pixel electrode PE3, the light emitting layer OL and the common electrode CE may form a third light-emitting element ED3. Each of the first light-emitting element ED1, the second light-emitting element ED2 and the third light-emitting element ED3 may emit a source light. The source light may be provided to the wavelength conversion layer WCL. For example, the source light may be, but is not limited to, blue light. It may be white light, or ultraviolet light. The first light-emitting element ED1, the second light-emitting element ED2 and the third light-emitting element ED3 may be organic light-emitting diodes.

The thin-film encapsulation layer TFEL may be located on the common electrode CE. The thin-film encapsulation layer TFEL may be located commonly across the first light-emitting area LA1, the second light-emitting area LA2, the third light-emitting area LA3, and the non-light-emitting area NLA. According to some embodiments of the present disclosure, the thin-film encapsulation layer TFEL may directly cover the common electrode CE.

According to some embodiments of the present disclosure, the thin-film encapsulation layer TFE may include a first inorganic encapsulation film 171, an organic encapsulation film 173 and a second inorganic encapsulation film 175 sequentially stacked on the common electrode CE.

Each of the first inorganic encapsulation layer 171 and the second inorganic encapsulation layer 175 may include at least one of: silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, or the like. The organic encapsulation film 173 may include an acrylic resin, a methacrylate-based resin, polyisoprene, a vinyl resin, an epoxy resin, an urethane resin, a cellulose resin and a perylene resin.

It is to be noted that the structure of the thin-film encapsulation layer TFEL is not limited to the above example. The stack structure of the thin-film encapsulation layer TFEL may be altered in a variety of ways.

The wavelength conversion layer WCL may be located on the light emitting element layer EML including the thin-film encapsulation layer TFEL.

The wavelength conversion layer WCL may include a bank 180, a first wavelength conversion pattern 230, a second wavelength conversion pattern 240, a light-transmitting pattern 250, and a capping layer 300.

The bank 180 may be located on the thin-film encapsulation layer TFEL. The bank 180 may partition the light-emitting areas LA1, LA2 and LA3 and the non-light-emitting area NLA. The bank 180 may be located in the non-light-emitting area NLA and can block the transmission of light. For example, the bank 180 may be located between the first wavelength conversion pattern 230, the second wavelength conversion pattern 240 and the light-transmitting pattern 250 to prevent or reduce color mixing between neighboring light-emitting areas.

The bank 180 may include an organic light-blocking material and may be formed via coating and exposure processes of the organic light-blocking material, or by inkjet printing. For example, the bank 180 may include an organic material and a dye or pigment that can block light mixed in the organic material. The organic material may include an acrylic resin, a methacrylate-based resin, polyisoprene, a vinyl resin, an epoxy resin, an urethane resin, a cellulose resin and a perylene resin. The dye or pigment may include carbon black, etc.

The first wavelength conversion pattern 230, the second wavelength conversion pattern 240 and the light-transmitting pattern 250 may be located on the thin-film encapsulation layer TFEL.

The first wavelength conversion pattern 230 may be located on the thin-film encapsulation layer TFEL in the first light-emitting area LA1. The first wavelength conversion pattern 230 may convert or shift the peak wavelength of the incident light into light of another peak wavelength and emit the light. According to some embodiments of the present disclosure, the first wavelength conversion pattern 230 may convert the source light provided from the first light-emitting element ED1 into red light having a peak wavelength in the range of approximately 610 nm to 650 nm to output it.

The first wavelength conversion pattern 230 may include a first base resin 231 and first wavelength shifters 235 dispersed in the first base resin 231, and may further include second scatterers 233 dispersed in the first base resin 231.

The first base resin 231 may be made of a material having a high light transmittance. According to some embodiments of the present disclosure, the first base resin 231 may be made of an organic material. For example, the first base resin 231 may include an organic material such as an epoxy resin, an acrylic resin, a cardo resin, or an imide resin.

The first scatterers 233 may have a refractive index different from that of the first base resin 231 and may form an optical interface with the first base resin 231. For example, the first scatterers 233 may be light scattering particles. The material of the first scatterers 233 is not particularly limited as long as they can scatter at least a portion of the transmitted light. For example, the scatterers 450 may be metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), etc. Examples of the material of the organic particles may include an acrylic resin, a urethane resin, etc. The first scatterers 233 can scatter light in random directions regardless of the direction in which the incident light is coming, without substantially changing the wavelength of the light transmitting the first wavelength conversion pattern 230.

The first wavelength shifters 235 may convert or shift the peak wavelength of the incident light to another peak wavelength. According to some embodiments of the present disclosure, the first wavelength shifters 235 may convert the source light provided from the first light-emitting element ED1, e.g., blue light into red light having a single peak wavelength in the range of approximately 610 nm to 650 nm.

Examples of the first wavelength shifters 235 may include quantum dots, quantum rods or phosphors. For example, quantum dots may be particulate matter that emits a color as electrons transition from the conduction band to the valence band.

The quantum dots may be semiconductor nanocrystalline material. The quantum dots have a specific band gap depending on their compositions and size, and can absorb light and emit light having an intrinsic wavelength. Examples of the semiconductor nanocrystals of the quantum dots may include Group IV nanocrystals, Groups II-VI compound nanocrystals, Groups III-V compound nanocrystals, Groups IV-VI nanocrystals, or combinations thereof.

The group II-VI compounds may be selected from the group consisting of: binary compounds selected from the group consisting of CdSe, CdTe, ZnS, ZnSe, ZnTe, ZnO, HgS, HgSe, HgTe, MgSe, MgS and a mixture thereof; ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and a mixture thereof; and quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and a mixture thereof.

The group III-V compounds may be selected from the group consisting of: binary compounds selected from the group consisting of GaN, GaP, GaAs, GaSb, AlN, AlP, AlAs, AlSb, InN, InP, InAs, InSb and a mixture thereof; ternary compounds selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and a mixture thereof; and quaternary compounds selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and a mixture thereof.

The group IV-VI compounds may be selected from the group consisting of: binary compounds selected from the group consisting of SnS, SnSe, SnTe, PbS, PbSe, PbTe and a mixture thereof; ternary compounds selected from the group consisting of SnSeS, SnSeTe, SnSTe, PbSeS, PbSeTe, PbSTe, SnPbS, SnPbSe, SnPbTe and a mixture thereof; and quaternary compounds selected from the group consisting of SnPbSSe, SnPbSeTe, SnPbSTe and a mixture thereof. The group IV elements may be selected from the group consisting of Si, Ge and a mixture thereof. The group IV compounds may be binary compounds selected from the group consisting of SiC, SiGe and a mixture thereof.

The binary compounds, the ternary compounds or the quaternary compounds may be present in the particles at a uniform concentration, or may be present in the same particles at partially different concentrations. In addition, they may have a core/shell structure in which one quantum dot surrounds another quantum dot. At the interface between the core and the shell, the gradient of the concentrate of atoms in the shell may decrease toward the center.

According to some embodiments of the present disclosure, the quantum dots may have a core-shell structure including a core comprising the nanocrystals and a shell surrounding the core. The shell of the quantum-dots may serve as a protective layer for maintaining the semiconductor properties by preventing or reducing chemical denaturation of the core and/or as a charging layer for imparting electrophoretic properties to the quantum dots. The shell may be either a single layer or multiple layers. Examples of the shell of the quantum dot may include an oxide of a metal or a non-metal, a semiconductor compound, a combination thereof, etc.

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄ and CoMn₂O₄.

In addition, examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

The light output from the first wavelength shifters 235 may have a full width at half maximum (FWHM) of the emission wavelength spectrum of approximately 45 nm or less, approximately 40 nm or less, or approximately 30 nm or less. Accordingly, the color purity and color gamut of the colors displayed by the display device 10 can be further improved. In addition, the light output from the first wavelength shifts 235 may travel in different directions regardless of the incidence direction of the incident light. In this manner, the side visibility of the first color displayed in the first light-emitting area LA1 can be improved.

Some of the source lights provided from the first light-emitting element ED1 may not be converted into red light by the first wavelength shifters 235. However, the lights that are not converted into red light may be blocked by the color filter layer CFL located thereabove. On the other hand, red light converted by the first wavelength conversion pattern 230 passes through the color filter layer CFL and exit to the outside.

The second wavelength conversion pattern 240 may be located on the thin-film encapsulation layer TFEL in the second light-emitting area LA2. The second wavelength-converting pattern 240 may convert or shift the peak wavelength of the incident light into light of another peak wavelength to emit the light. According to some embodiments of the present disclosure, the second wavelength conversion pattern 240 may convert the source light provided from the second light-emitting element ED2 into green light in the range of 510 nm to 550 nm (or approximately 510 nm to 550 nm) to output it.

The second wavelength conversion pattern 240 may include a second base resin 241 and second wavelength shifters 245 dispersed in the second base resin 241, and may further include second scatterers 243 dispersed in the first base resin 241.

The second base resin 241 may be made of a material having a high light transmittance. According to some embodiments of the present disclosure, the second base resin 241 may be made of an organic material. The second base resin 241 may be made of the same material as the first base resin 231, or may include at least one of the materials listed above as the examples of the constituent materials of the first base resin 231.

The second wavelength shifters 245 may convert or shift the peak wavelength of the incident light to another peak wavelength. According to some embodiments of the present disclosure, the second wavelength shifters 245 may convert the source light having a peak wavelength in the range of 440 nm to 480 nm, e.g., blue light into green light having a peak wavelength in the range of 510 nm to 550 nm.

Examples of the second wavelength shifters 245 may include quantum dots, quantum rods or phosphors. The second wavelength shifters 245 are identical (or substantially identical) to the first wavelength shifters 235; and, therefore, some redundant description may be omitted. According to some embodiments of the present disclosure, the first wavelength shifters 235 and the second wavelength shifters 245 may all be made up of quantum dots. In such case, the particle size of the quantum dots forming the first wavelength shifters 235 may be greater than the particle size of the quantum dots forming the second wavelength shifters 245.

The second scatterers 243 may have a refractive index different from that of the second base resin 241 and may form an optical interface with the second base resin 241. For example, the second scatterers 243 may be light scattering particles. The second scatterers 243 are identical (or substantially identical) to the first scatterers 233 described above; and, therefore, some redundant description may be omitted.

The source light output from the second light-emitting element ED2 may be provided to the second wavelength conversion pattern 240. The second wavelength shifters 245 may convert the source light provided from the second light-emitting element ED2 into green light having a peak wavelength in the range of approximately 510 nm to 550 nm to output it.

Some of the source lights may not be converted into green light by the second wavelength shifters 245 and may pass through the second wavelength conversion pattern 240. However, light that is not converted to green light may be blocked by the color filter layer CFL. On the other hand, green light converted by the second wavelength conversion pattern 240 passes through the color filter layer CFL and exit to the outside.

The light-transmitting pattern 250 may be located on the thin-film encapsulation layer TFEL. The light-transmitting pattern 250 may be in line with the third light-emitting area LA3. The light-transmitting pattern 250 can transmit incident light. If the source light provided from the third light-emitting element ED3 is blue light, the blue source light may pass through the light-transmitting pattern 250.

According to some embodiments of the present disclosure, the light-transmitting pattern 250 may include a third base resin 251 and may further include third scatterers 253 dispersed in the third base resin 251.

The third base resin 251 may be made of a material having a high light transmittance. According to some embodiments of the present disclosure, the third base resin 251 may be made of an organic material. The third base resin 251 may be made of the same material as the first base resin 231 or the second base resin 241, or may include at least one of the materials listed above as the examples of the constituent materials of the first base resin 231.

The third scatterers 253 may have a refractive index different from that of the third base resin 251 and may form an optical interface with the third base resin 251. The third scatterers 253 are identical (or substantially identical) to the first scatterers 233 described above; and, therefore, some redundant description may be omitted.

According to some embodiments of the present disclosure, the first wavelength conversion pattern 230, the second wavelength conversion pattern 240 and the light-transmitting pattern 250 may be formed by applying a photosensitive material and exposing and developing the photosensitive material. It should be understood, however, that the present disclosure is not limited thereto. The first wavelength conversion pattern 230, the second wavelength conversion pattern 240 and the light-transmitting pattern 250 may be formed by inkjet printing.

The capping layer 300 may be located on the bank 180, the first wavelength conversion pattern 230, the second wavelength conversion pattern 240, and the light-transmitting pattern 250 to cover them. Thus, it may be possible to prevent or reduce instances of contaminants or impurities such as moisture and air permeating from the outside to damage or contaminate the bank 180, the first wavelength conversion pattern 230, the second wavelength conversion pattern 240 and the light-transmitting pattern 250.

The capping layer 300 may be made of an inorganic material. For example, the capping layer 300 may be made of a material including silicon nitride, aluminum nitride, zirconium nitride, titanium nitride, hafnium nitride, tantalum nitride, silicon oxide, aluminum oxide, titanium oxide, tin oxide, silicon oxynitride, etc.

The opposing substrate TSUB may face the substrate SUB, the color filter layer CFL may be located on a surface of the opposing substrate TSUB, and the auxiliary layer AUL may be located on a surface of the color filter layer CFL.

The color filter layer CFL may include a first color filter 360, a second color filter 370, and a third color filter 380. In addition, it may include a first color pattern 365, a second color pattern 375, and a third color pattern 385.

The first color filter 360 may be located between the opposing substrate TSUB and the auxiliary layer AUL, and may be arranged in line with the third light-emitting area LA3. The first color filter 360 may overlap with the light-transmitting pattern 250 and may be covered by the auxiliary layer AUL. The first color pattern 365 may be spaced apart from the first color filter 360 and may be arranged in line with the non-light-emitting area NLA.

The first color filter 360 and the first color pattern 365 may selectively transmit light of the third color (e.g., blue light) and may block or absorb light of the first color (e.g., red light) and light of the second color (e.g., green light). According to some embodiments, the first color filter 360 may be a blue color filter and may include a blue colorant such as a blue dye and a blue pigment. As used herein, the colorant encompasses a dye as well as a pigment.

The second color filter 370 may be located between the opposing substrate TSUB and the auxiliary layer AUL, and may be arranged in line with the first light-emitting area LA1. The second color filter 370 may overlap with the first light-emitting element ED1 and the first wavelength conversion pattern 230. According to some embodiments, one side of the second color filter 370 may be located in the non-light-emitting area NLA and overlap with the adjacent first color filter 360. The opposite side of the second color filter 370 may be located in the non-light-emitting area NLA and overlap with the first color pattern 365. The second color pattern 375 may be spaced apart from the second color filter 370 and may be arranged in line with the non-light-emitting area NLA. The second color pattern 375 may overlap with the first color filter 360 in the non-light-emitting area NLA. The second color filter 370 may be covered by the auxiliary layer AUL.

The second color filter 370 and the second color pattern 375 may selectively transmit light of the first color (e.g., red light) and may block and absorb light of the second color (e.g., green light) and light of the third color (e.g., blue light). For example, the second color filter 370 may be a red color filter and may include a red colorant such as a red dye and a red pigment.

The third color filter 380 may be located between the opposing substrate TSUB and the auxiliary layer AUL, and may be arranged in line with the second light-emitting area LA1. The third color filter 380 may overlap with the second light-emitting element ED2 and the second wavelength conversion pattern 240. According to some embodiments, one side of the third color filter 380 may be arranged in the non-light-emitting area NLA and overlap with the adjacent first color filter 360 and the first color pattern 365. In addition, the opposite side of the third color filter 380 may be located in the non-light-emitting area NLA and overlap with the adjacent first color filter 360 and the second color pattern 375. The third color pattern 385 may be spaced apart from the third color filter 380 and may be arranged in line with the non-light-emitting area NLA. The third color pattern 385 may overlap with the first color filter 360 and the second color filter 370 in the non-light-emitting area NLA. The third color filter 380 and the third color pattern 385 may be covered by the auxiliary layer AUL.

The third color filter 380 may selectively transmit light of the second color (e.g., green light) and may block and absorb light of the first color (e.g., red light) and light of the third color (e.g., blue light). For example, the third color filter 380 may be a green color filter and may include a green colorant such as a green dye and a green pigment.

As described above, the first to third color filters 360, 370 and 380 and the first to third color patterns 365, 375 and 385 overlap each other in the non-light-emitting area NLA to block or absorb light. For example, in the non-light-emitting area NLA located on one side of the second light-emitting area LA2, the first color pattern 365, the second color filter 370 and the third color filter 380 overlap one another, and in the non-light-emitting area NLA located on the opposite side of the second light-emitting area LA2, the first color filter 360, the second color pattern 375 and the third color filter 380 may overlap one another.

The auxiliary layer AUL may cover the color filter layer CFL. The auxiliary layer AUL may be an adhesive auxiliary layer that can improve the coupling strength of the binding member PPA, which will be described later. The auxiliary layer AUL is arranged to entirely cover the color filter layer CFL, and may be located at least in the display area DPA of the display device 10. It should be understood, however, that the present disclosure is not limited thereto. The auxiliary layer AUL may be extended to the non-display area NDA of the display device 10.

The auxiliary layer AUL may include a transparent resin that allows light to pass through. In addition, the auxiliary layer AUL may include a material that allows amine (NH₂), which can be bonded with the epoxy group of the binding member PPA, to easily adhere to the surface. For example, the auxiliary layer AUL may include one or more of a silicone resin, an acrylic resin, an epoxy resin, a polyethylene resin, and an ester resin. According to some embodiments of the present disclosure, the auxiliary layer AUL may be a silicone resin, and the silicone resin may be polydimethylsiloxane (PDMS). Amine groups may be bonded to the surface of the auxiliary layer AUL by a fabrication method described later.

The auxiliary layer AUL may have a refractive index (e.g., a set or predetermined refractive index) for light conversion efficiency. The refractive index of the auxiliary layer AUL may be 1.3 to 1.5. With the refractive index of the auxiliary layer AUL of 1.3 or higher, the light output from the wavelength conversion layer WCL is reflected due to the difference in refractive index with the air layer AIL, which will be described later, and may be reused for light conversion, thereby improving light conversion efficiency. With the refractive index of the auxiliary layer AUL of 1.5 or less, it may be possible to prevent or reduce deterioration of matching characteristics of the refractive index between the auxiliary layer AUL and adjacent layers.

The auxiliary layer AUL may have a modulus (e.g., a set or predetermined modulus) to improve adhesion with the binding member PPA, which will be described later. The modulus of the auxiliary layer AUL may be 100 MPa to 1 GPa. With the modulus of the auxiliary layer AUL of 100 MPa or more, the gap between the opposing substrate TSUB and the substrate SUB can be well maintained to form the air layer AIL to be described later. With the modulus of the auxiliary layer AUL of 1 GPa or less, physical adhesion with the binding member PPA, which will be described later, can be improved.

The thickness of the auxiliary layer AUL may be 1 to 5 μm. With the thickness of the auxiliary layer AUL of 1 μm or higher, the auxiliary layer AUL can be coated reliably and have a flat surface, making the process easier. With the thickness of the auxiliary layer AUL of 5 μm or less, a thin display device 10 can be implemented by reducing the gap between the substrate SUB and the opposing substrate TSUB.

The binding member PPA may be located between the wavelength conversion layer WCL and the auxiliary layer AUL. The binding member PPA is for coupling the substrate SUB with the opposing substrate TSUB. For example, binding member PPA may be in direct contact with the wavelength conversion layer WCL located on the substrate SUB and the auxiliary layer AUL located on the opposing substrate TSUB to couple them together. The binding member PPA may maintain the gap between the substrate SUB and the opposing substrate TSUB. For example, the binding member PPA may maintain the gap between the capping layer 300 and the auxiliary layer AUL.

The binding member PPA may be arranged such that it overlaps with none of the first light-emitting area LA1, the second light-emitting area LA2, and the third light-emitting area LA3. The binding member PPA may be arranged in line with the non-light-emitting area NLA and may be in line with the bank 180 of the wavelength conversion layer WCL.

The binding member PPA may be an adhesive that can be patterned via a photo process. As will be described later, the binding member PPA may be formed in the non-light-emitting area NLA by being applied on the capping layer 300 and then patterned via a photo process. In addition, the binding member PPA may include an epoxy resin having an epoxy group.

The thickness of the binding member PPA may be 0.1 to 4.5 μm. With the thickness of the binding member PPA of 0.1 μm or higher, the gap between the substrate SUB and the opposing substrate TSUB can be maintained to prevent or reduce damage to structures during the coupling process. With the thickness of the binding member PPA of 4.5 μm or less, the gap of the display device 10 is not increased, and accordingly a thin display device 10 can be implemented.

The modulus of the binding member PPA may be 2 GPa to 10 GPa. With the modulus of the binding member PPA within the above range, it can be reliably bonded with the auxiliary layer AUL while maintaining the gap between the substrate SUB and the opposing substrate TSUB. The adhesive strength of the binding member PPA may be, but is not limited to, approximately 200 Kfg. It may range from 150 Kfg to 300 Kfg.

Referring to FIGS. 7 and 8, the binding member PPA may be attached to the auxiliary layer AUL of the opposing substrate TSUB. The binding member PPA may include an epoxy resin with an epoxy group exposed on the surface. As will be described later, the auxiliary layer AUL may have an amine group (—NH2) located on its surface. When the binding member PPA and the auxiliary layer AUL are physically attached together, the epoxy group of the binding member PPA and the amine group of the auxiliary layer AUL may be chemically bonded by heat treatment. For example, the amine group and the epoxy group may be covalently bonded and attached together using intermolecular forces.

According to some embodiments of the present disclosure, because the epoxy group of the binding member PPA and the amine group of the auxiliary layer AUL are bonded physically as well as chemically, the bonding strength is excellent and no hydrolysis occurs, so that the reliability of the bonding can be improved.

Incidentally, the air layer AIL may be located in the space defined by the binding member PPA, the auxiliary layer AUL and the capping layer 300. The air layer AIL may overlap with the light-emitting areas LA1, LA2 and LA3 and partially with the non-light-emitting area NLA. The air layer AIL may be formed via a process of attaching the substrate SUB to the opposing substrate TSUB.

Some of the lights emitted from the light-emitting elements ED1, ED2 and ED3 may be converted in the wavelength conversion layer WCL and exit upward, while some others may be totally reflected due to the difference in the refractive index between the capping layer 300 and the air layer AIL, may be incident again on the wavelength conversion layer WCL and may be used for light conversion. Accordingly, the air layer AIL between the capping layer 300 and the auxiliary layer AUL can improve the light conversion efficiency of the display device 10, which may contribute to improving light efficiency.

Referring to FIG. 9, according to some embodiments of the present disclosure, the binding member PPA may be located in the non-light-emitting area NLA and may have a mesh pattern when viewed from the top (e.g., in a plan view). In this instance, the air layer AIL may be spaced apart from another one in an island shape.

Referring to FIG. 10, according to some embodiments of the present disclosure, binding members PPA may be located in the non-light-emitting area NLA and may be formed in a dot pattern when viewed from the top (e.g., in a plan view). One or more binding members PPA may be located between the light-emitting areas LA1, LA2 and LA3 and may be equally spaced apart from each other. It should be understood, however, that the present disclosure is not limited thereto. The binding members PPA may be spaced apart from one another at different distances. In this instance, the air layer AIL may be located entirely in the display area excluding the binding members PPA. For example, the air layer AIL may be arranged to overlap each of the light-emitting areas LA1, LA2 and LA3 and the non-light-emitting area NLA.

The area of the upper surface of a binding member PPA may be 60% or more of the area of the lower surface. For example, the area of the upper surface of the binding member PPA may be smaller than, equal to, or greater than the area of the lower surface. According to some embodiments of the present disclosure, the area of the upper surface of a binding member PPA may range 60% to 1000% of the area of the lower surface. It is, however, to be understood that the present disclosure is not limited thereto. The cross-sectional shape of the binding members PPA may be symmetrical or asymmetric. For example, the cross-sectional shape of the binding members PPA may be regular trapezoidal, inverted trapezoidal, or rectangular.

The taper angle of the binding member PPA may be 20° to 170°. According to some embodiments, the taper angle of the binding member PPA may be 40° to 130°. The area of the upper surface of the binding member PPA may range from 60% to 1000% of the area of the lower surface.

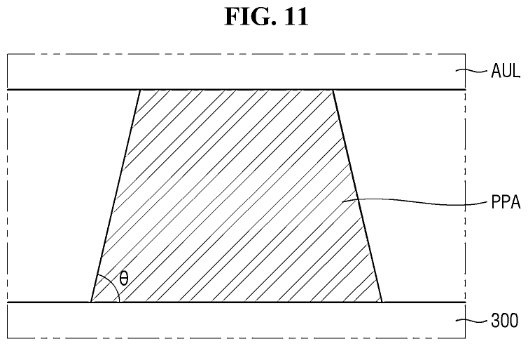

FIGS. 11 to 13 are cross-sectional views showing examples of various shapes of binding members.

Referring to FIG. 11, the area of the upper surface of the binding member PPA may be equal to or greater than 60% and less than 100% of the area of the lower surface. In this instance, the cross-sectional shape of the binding member PPA may be an isosceles trapezoid, and the taper angle θ may be an acute angle.

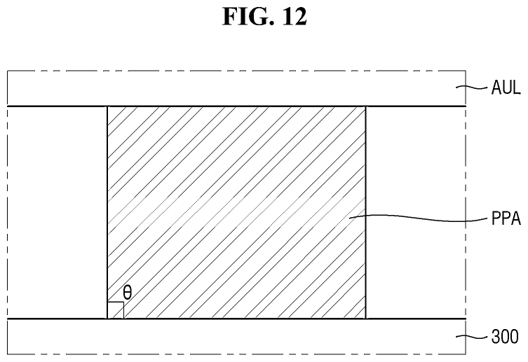

Referring to FIG. 12, the area of the upper surface of the binding member PPA may be 100% of the area of the lower surface. In other words, the area of the upper surface of the binding member PPA may be equal to the lower surface. In this instance, the cross-sectional shape of the binding member PPA may be a rectangle, and the taper angle θ may be a right angle.

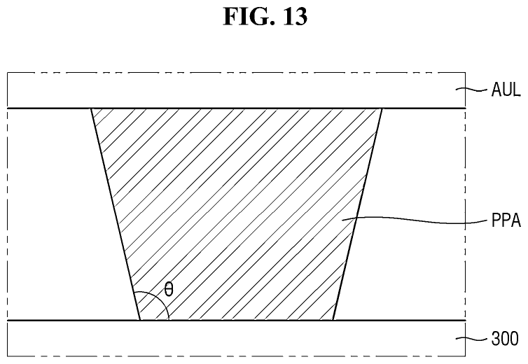

Referring to FIG. 13, the area of the upper surface of the binding member PPA may be greater than 100% and equal to or less than 1000% of the area of the lower surface. In this instance, the cross-sectional shape of the binding member PPA may be an inverted trapezoid, and the taper angle θ may be an obtuse angle.

As described above, in the display device 10 according to some embodiments, the auxiliary layer AUL is located on the color filter layer CFL and the binding member PPA is located on the wavelength conversion layer WCL and they are coupled with each other, so that the substrate SUB and the opposing substrate TSUB can be more reliably coupled together. In addition, the air layer AIL is formed between the wavelength conversion layer WCL and the auxiliary layer AUL, so that the light conversion efficiency and light efficiency can be improved.

Hereinafter, a method of fabricating the display device 10 according to some embodiments as shown in FIG. 6 will be described in more detail.

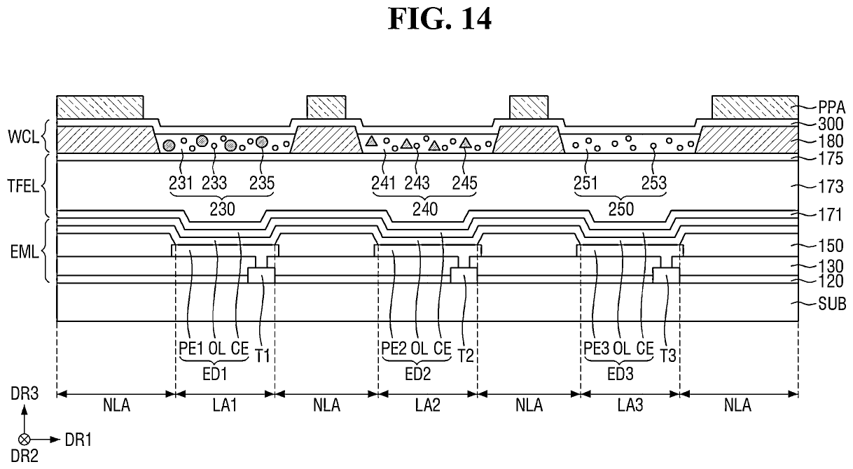

FIGS. 14 to 16 are cross-sectional views showing processing steps of a method of fabricating a display device according to some embodiments of the present disclosure.

Referring to FIG. 14, a plurality of switching elements T1, T2 and T3, a plurality of light-emitting elements ED1, ED2 and ED3, first and second insulating layers 120 and 130 and a pixel-defining layer 150 are formed on the substrate SUB, so that a light emitting element layer EML is formed. A first inorganic encapsulation layer 171, an organic encapsulation layer 173 and a second inorganic encapsulation layer 175 are formed on the light emitting element layer EML, to form a thin-film encapsulation layer TFEL.

The light emitting element layer EML and the thin-film encapsulation layer TFEL located on the substrate SUB may be formed by depositing materials forming the layers, such as a metal material, and patterning the materials using a mask. In addition, the first and second insulating layers 120 and 130 and the pixel-defining layer 150 may be formed by applying a material forming each layer, such as an insulating material, or via a patterning process using a mask, if necessary. The structure of the plurality of layers located on the substrate SUB has been described above; and, therefore, some redundant descriptions may be omitted.

Subsequently, banks 180 are patterned on the thin-film encapsulation layer TFEL. Between the banks 180, a first wavelength conversion pattern 230 is formed in the first light-emitting area LA1, a second wavelength conversion pattern 240 is formed in the second light-emitting area LA2, and a light-transmitting pattern 250 is formed in the third light-emitting area LA3. The first wavelength conversion pattern 230 and the second wavelength conversion pattern 240 may be formed using inkjet printing, and the light-transmitting pattern 250 may be formed via a photo process. In addition, a capping layer 300 is stacked on the banks 180, the first wavelength conversion pattern 230, the second wavelength conversion pattern 240 and the light-transmitting pattern 250, to form a wavelength conversion layer WCL.

Subsequently, a bonding coating layer is formed on the wavelength conversion layer WCL and then is patterned to form a binding member PPA. The binding member PPA is in line with the non-light-emitting area NLA but not with the light-emitting areas LA1, LA2 and LA3.

The binding member PPA may be formed as an adhesive that can be patterned via a photo process. The binding member PPA may include an epoxy resin or a mixture of an epoxy resin and a novalac resin, containing a photoinitiator, a solvent, and a photo active compound (PAC). The content of the epoxy resin in the solid content of the total bond coating layer composition may be 15 to 100 wt %. In particular, the bonding coating layer may include a photoresist, so that a binding member PPA may be formed with a composition allowing for photo processing. Either positive photo process or negative photo process may be possible depending on the photoresist.

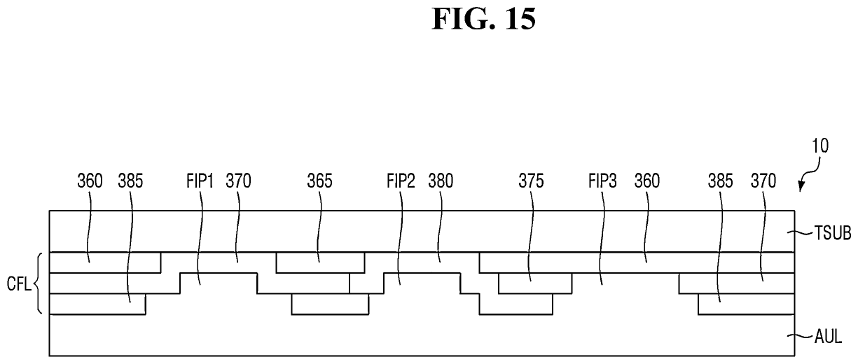

Subsequently, referring to FIG. 15, a first color filter material is applied on the opposing substrate TSUB and is patterned, forming the first color filter 360 and the first color pattern 365. Subsequently, a second color filter material is applied on the opposing substrate TSUB and is patterned, forming a second color filter 370 and a second color pattern 375. Subsequently, a third color filter material is applied on the opposing substrate TSUB and is patterned, forming a third color filter 380 and a third color pattern 385.

Then, the auxiliary layer AUL is coated on the color filter layer CFL. The auxiliary layer AUL is formed to have a thickness of 1 to 5 μm. The auxiliary layer AUL may be formed using a solution process, such as spin coating, slit coating and inkjet printing, The auxiliary layer AUL may be cured by applying UV light and heat.

Subsequently, surface treatment is performed on the opposing substrate TSUB where the auxiliary layer AUL is formed. The surface treatment may be performed using nitrogen plasma, especially atmospheric-pressure nitrogen plasma, or vacuum nitrogen plasma. By performing the surface treatment using nitrogen plasma, hydrogen and nitrogen of the auxiliary layer AUL combine on the surface of the auxiliary layer AUL, so that an amine group (NH₂) may be attached.

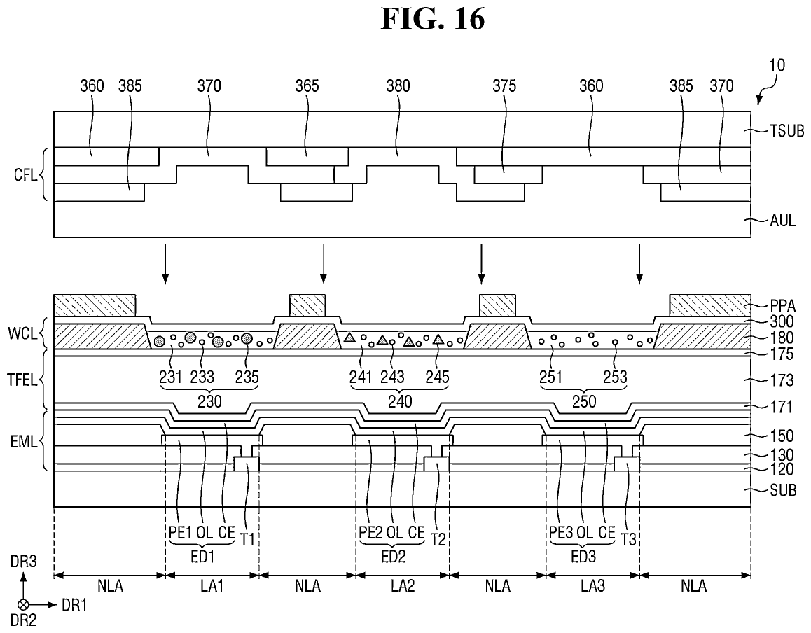

Subsequently, referring to FIG. 16, the opposing substrate TSUB is aligned on the substrate SUB. In doing so, the substrate SUB and the opposing substrate TSUB are aligned so that the auxiliary layer AUL faces the binding member PPA. Then, the opposing substrate TSUB and the substrate SUB are pressed and bonded together. When the opposing substrate TSUB and the substrate SUB are bonded, the first color filter 360 is aligned with the third light-emitting area LA3, the second color filter 370 is aligned with the first light-emitting area LA1, and the third color filter 380 is aligned with the second light-emitting area LA2.

The bonding process of the opposing substrate TSUB and the substrate SUB may be vacuum bonding. The vacuum bonding applies a pressure of up to 100,000 MPa, which can improve the physical adhesion between the binding member PPA of the substrate SUB and the auxiliary layer AUL of the opposing substrate TSUB. In particular, even if the thickness of the binding member PPA is non-uniform, physical adhesion between the binding member PPA and the auxiliary layer AUL can become reliable because such a large pressure is applied by the vacuum bonding.

Subsequently, after the opposing substrate TSUB and the substrate SUB are attached together, heat treatment is performed on the attached panel. The heat treatment may cause the amine group and the epoxy group to react and chemically bond the amine group with the epoxy group by covalent bond. The heat treatment may be performed in an oven at 90 to 110° C. for 30 to 60 minutes. In this manner, the display device 10 in which the substrate SUB and the opposing substrate TSUB are attached together as shown in FIG. 6 can be fabricated.

By the method of fabricating the display device 10 according to some embodiments, it may be possible to strengthen the coupling between the substrate SUB and the opposing substrate TSUB by not only physical coupling between the binding member PPA and the auxiliary layer AUL but also the chemical bonding therebetween. In particular, by virtue of the chemical bonding between the binding member PPA and the auxiliary layer AUL, it may be possible to avoid the adhesion therebetween from being lowered even in a high-temperature and high-humidity environment.

In concluding the detailed description, those skilled in the art will appreciate that many variations and modifications can be made to the disclosed embodiments without substantially departing from the spirit and scope of embodiments according to the present invention. Therefore, the disclosed embodiments of the invention are used in a generic and descriptive sense only and not for purposes of limitation.

What is claimed is:

1. A display device comprising:
a substrate comprising light-emitting areas and a non-light-emitting area;
a light emitting element layer on the substrate;
a thin-film encapsulation layer on the light emitting element layer;
a wavelength conversion layer on the thin-film encapsulation layer;
a binding member on the wavelength conversion layer and comprising an epoxy group;
an opposing substrate facing the substrate;
a color filter layer on a surface of the opposing substrate; and
an auxiliary layer on the color filter layer and comprising an amine group,
wherein the binding member and the auxiliary layer are in contact with each other, and the epoxy group of the binding member and the amine group of the auxiliary layer are chemically bonded to each other.

2. The display device of claim 1, wherein the binding member overlaps the non-light-emitting area and not overlap with the light-emitting areas.

3. The display device of claim 2, wherein the auxiliary layer overlaps the light-emitting areas and the non-light-emitting area.

4. The display device of claim 2, wherein the binding member and the auxiliary layer are in contact with each other in the non-light-emitting area.

5. The display device of claim 1, wherein the binding member comprises an epoxy resin.

6. The display device of claim 1, wherein the auxiliary layer has a refractive index in a range of 1.3 to 1.5.

7. The display device of claim 1, wherein a modulus of the auxiliary layer is in a range of 100 MPa to 1 GPa.

8. The display device of claim 1, wherein the auxiliary layer has a thickness in a range of 1 μm to 5 μm.

9. The display device of claim 1, wherein the binding member has a thickness in a range of 0.1 μm to 4.5 μm.

10. The display device of claim 1, further comprising:
an air layer in a space defined by the auxiliary layer, the binding member and the wavelength conversion layer,
wherein the air layer overlaps the light-emitting areas.

11. The display device of claim 1, wherein the binding member is arranged in a mesh pattern or a dot pattern in a plan view.

12. The display device of claim 1, wherein a taper angle of the binding member is in a range of 20° to 170°.

13. The display device of claim 1, wherein the light emitting element layer comprises a pixel electrode, a bank covering an edge of the pixel electrode, a light emitting layer on the pixel electrode, and a common electrode on the light emitting layer.

14. The display device of claim 1, wherein the light-emitting areas comprise a first light-emitting area configured to emit red light, a second light-emitting area configured to emit green light, and a third light-emitting area configured to emit blue light, and
wherein the wavelength conversion layer comprises a first wavelength conversion pattern in line with the first light-emitting area, a second wavelength conversion pattern in line with the second light-emitting area, and a light-transmitting pattern in line with the third light-emitting area.

15. A method of fabricating a display device, the method comprising:
preparing a substrate provided with an light emitting element layer, a thin-film encapsulation layer, and a wavelength conversion layer;
forming a binding member comprising an epoxy group on the substrate;
preparing an opposing substrate provided with a color filter layer;
forming an auxiliary layer on the color filter layer;
attaching an amine group to a surface of the auxiliary layer by performing surface treatment on the auxiliary layer;
aligning and attaching the substrate with the opposing substrate to couple the binding member with the auxiliary layer; and
performing a heat treatment process on the attached panel.

16. The method of claim 15, wherein the binding member is formed by applying a bonding coating layer and patterning the bonding coating layer via a photo process.

17. The method of claim 15, wherein the performing surface treatment comprises using atmospheric-pressure nitrogen plasma or vacuum nitrogen plasma.

18. The method of claim 15, wherein the heat treatment process is performed at a temperature in a range of 90° C. to 110° C. for 30 to 60 minutes.

19. The method of claim 15, wherein the amine group of the auxiliary layer and the epoxy group of the binding member are chemically bonded together in the heat treatment process.

20. The method of claim 15, wherein the substrate and the opposing substrate are bonded together by vacuum bonding.
